(19) United States
(12) Patent Application Publication
(10) Pub. No.: US 2012/0187940 A1
(43) Pub. Date: Jul. 26, 2012

(54) DEVICE FOR DETECTING THE POSITION OF A SHIFT AND/OR SELECTOR LEVER FOR A TRANSMISSION AND SHIFT DEVICE FOR THE TRANSMISSION OF A MOTOR VEHICLE

(75) Inventor: Falk Uhlenbruck, Werne (DE)

(73) Assignee: ECS Engineered Control Systems AG

(21) Appl. No.: 13/496,962

(22) PCT Filed: Nov. 17, 2010
(86) PCT No.: PCT/EP10/67679

§ 371 Date: Mar. 19, 2012

(30) Foreign Application Priority Data
Nov. 20, 2009 (DE) 10 2009 053 873.9

(51) Int. Cl. G01B 7/14; G01R 33/00

(52) U.S. Cl. 324/207.11

(57) ABSTRACT

A device (100) for detecting the position of a gearshift lever and/or selector lever (1) for a transmission has a signal-generating element (2.1; 2.2) that can be moved together with the gearshift lever and/or selector lever (1). The detection device (100) also has, as the measuring transducer, at least one sensor element (3, 4) that detects the signal from the signal-generating element (2.1; 2.2). A locking means (5) for the gearshift lever and/or selector lever (1) is associated with the signal-generating element (2.1; 2.2). The sensor element (3, 4) delivers, as the measured value, an analog signal (S1, S2) that is dependent on the plus-minus sign. A shifting device (200) for a transmission, especially for use in a motor vehicle, may include the device (100) for detecting the position of a gearshift lever and/or selector lever (1).

### CROSS-REFERENCE TO RELATED APPLICATIONS

This application is a national stage application (under 35 U.S.C. §371) of PCT/EP2010/067679, filed Nov. 17, 2010, which claims benefit of German application 10 2009 053 873.9, filed Nov. 20, 2009.

### TECHNICAL FIELD AND STATE OF THE ART

The invention relates to a device for detecting the position of a gearshift lever and/or selector lever for a transmission, comprising a signal-generating element that can be moved together with the gearshift lever and/or selector lever, and comprising, as the measuring transducer, at least one sensor element that detects the signal from the signal-generating element. The invention also relates to a shifting device for a transmission, especially for use in a motor vehicle, having a device for detecting the position of a gearshift lever and/or selector lever.

Motor vehicles normally have a shifting device with a gearshift lever and/or selector lever for shifting the transmission. Depending on the design of the transmission, the gearshift lever and/or selector lever can be moved in one or more shift gates. For instance, the gearshift lever and/or selector lever can select various automatically selectable modes such as, for example, P, R, M, D in a first shift gate, and it can be switched over from this first shift gate into a second shift gate in which individual gears that can be shifted manually can be selected. For this purpose, the gearshift lever and/or selector lever is pivotably mounted on a link, whereby the gearshift lever and/or selector lever can be pivoted around a first axis of rotation in order to shift in one shift gate, and then around a second axis of rotation in order to shift from the one shift gate into another shift gate.

The prior-art shifting devices normally have a locking mechanism, for instance, in the form of latching and counter-latching means that mark prescribed shifting positions for the gearshift lever and/or selector lever and preferably hold the gearshift lever and/or selector lever with a positive fit when it has been moved into the appropriate position. Such locking means are usually arranged at the lower free end of the gearshift lever and/or selector lever.

In order to actuate the transmission as a function of the position of the gearshift lever and/or selector lever, German patent DE 10 2008 028 618 B3 discloses a magnetic rotational-angle sensor arrangement for directly detecting the angular position or the rotational movement of the gearshift lever and/or selector lever. In this context, the sensor elements of the prior-art sensor arrangement deliver signals to an electric control unit that actuates the transmission of the motor vehicle by means of at least one actuator. For purposes of detecting the rotational angle of the gearshift lever and/or selector lever, the prior-art rotational-angle sensor arrangement is located in the vicinity of one of the pivoting axes of the gearshift lever and/or selector lever. In order to attain optimal detection of the position of the gearshift lever and/or selector lever, auxiliary components are needed for the sensor arrangement. These additional components increase the complexity of the entire unit and render their production and installation quite complicated. Since each component also displays a certain manufacturing tolerance, additional auxiliary components influence the degree of precision that can be achieved when it comes to detecting the position of the gearshift lever and/or selector lever.

European patent application EP 1 752 688 A1 discloses a shift-by-wire shifting device having a selector lever that can be actuated by an operator in order to remotely control the transmission of a motor vehicle. The shift-by-wire shifting device has pre-tensioning devices that keep one end of the selector lever in contact with a profiled surface in order to give the operator the sensation of shifting. Furthermore, detection devices containing transmitting means and receiving means are provided, whereby the transmitting means or the receiving means are installed at the end of the selector lever in such a way that the position of the end of the selector lever on the profiled surface can be detected. Every possible setting position of the selector lever is associated with a sensor of its own.

There exists a need for taking a device for detecting the position of a gearshift lever and/or selector lever having the above-mentioned features and refining it in such a manner that it can be easily produced and readily installed. By the same token, it should be possible to very precisely detect the position of the gearshift lever or selector lever. Moreover, a corresponding shifting device for the transmission of a motor vehicle is also to be proposed.

### SUMMARY OF THE INVENTION

A device for detecting the position of a gearshift lever and/or selector lever is suitable for regulating the functions of a transmission or drive, especially of a motor vehicle. In this context, the device can interact with the gearshift lever of a manual transmission or with a selector lever of an automatic transmission. It is also possible for the device to interact with the gearshift lever and/or selector lever of a combined transmission that has an automatic mode as well as an additional manual shifting function for manually shifting the gears.

The device for detecting the position of a gearshift lever and/or selector lever has at least one signal-generating element that can be moved together with the gearshift lever and/or selector lever. The device also has at least one sensor element which detects the signal of the signal-generating element and which serves as a measuring transducer.

It is provided that the signal-generating element is associated with a locking means for the gearshift lever and/or selector lever. Thanks to this measure, the position of the gearshift lever and/or selector lever is detected in the immediate vicinity of those means that serve to secure the gearshift lever and/or selector lever in prescribed positions, for example, in a shift gate, or positions for changing from one shift gate into another shift gate. As a result, the position of the gearshift lever and/or selector lever in the selectable shifting positions or gear positions that are prescribed, for instance, by the link of a shifting device can be detected with great precision. Consequently, the position of the gearshift lever and/or selector lever can be reliably detected since sources of error are avoided that might cause falsifications of the measured values due to the requisite auxiliary components. Therefore, the device accounts for a high level of functional reliability during the actuation of the transmission or drive of a motor vehicle by means of the gearshift lever and/or selector lever. Since there is no need for auxiliary components for detecting the position of the gearshift lever and/or selector lever, the device can also be realized in a simple manner.

The term “locking means” as set forth in this application refers to those means that serve to secure the gearshift lever and/or selector lever in selectable shifting positions, for example, in a shift gate. The gearshift lever and/or selector lever is secured in the locked positions, and preferably can only be released again if an appropriate shifting force is applied by the operator of the gearshift lever and/or selector lever. The locking means can be part of the gearshift lever and/or selector lever. In the installed state, the locking means preferably is attached to the gearshift lever and/or selector lever, preferably so as to be movable. Examples of locking means are latching means, clamping means or tensioning means.

According to a first embodiment of the invention, it is provided that the signal-generating element is firmly connected to the locking means. As a result, the detection of the position of the gearshift lever and/or selector lever is ensured in a very reliable manner since the firm connection of the signal-generating element and the locking means prevents the occurrence of any delays between the time when the detection device responds and the movement of the gearshift lever and/or selector lever into another position.

According to another embodiment of the invention, it is provided that the signal-generating element is arranged inside the locking means. This ensures that the signal-generating element can exercise the securing function of the locking means with respect to the gearshift lever and/or selector lever without any difficulties. Moreover, the arrangement of the signal-generating element in this manner also means that it is protected against external mechanical influences.

This is also the aim of the measure of another embodiment of the invention in which the locking means is a plastic part and the signal-generating element is at least partially surrounded by the material of the locking means. Moreover, configuring the locking means as a plastic part allows the signal-generating element to be integrated into the locking means in a particularly easy and cost-effective manner.

Preferably, the signal-generating element is a magnet. As a result, the position of the gearshift lever and/or selector lever can be detected contact-free very easily and cost-effectively, for example, in that the magnetic field strength is detected as a measured quantity by the at least one sensor element.

The signal-generating element can be realized particularly cost-effectively when it is a permanent magnet.

According to one embodiment of the invention, it can be provided that the signal-generating element is a magnet whose poles are arranged one behind the other as seen in the direction of the sensor element. In this embodiment, the signal-generating element is configured as a so-called diametric magnet. Consequently, when the gearshift lever and/or selector lever is shifted from one shifting position into another shifting position, the magnetic field can be reversed, depending on the position of the sensor element with respect to the signal-generating element. This reversal of the magnetic field can be detected by means of the sensor element on the basis of a change in the plus-minus sign of the detected magnetic field strength. Due to the change in the plus-minus sign, the signal that is generated by the signal-generating element and that can be detected by the sensor element thus contains additional information that can be evaluated. This means that the position of the gearshift lever and/or selector lever can detected very reliably and accurately.

As an alternative, of course, it can also be provided that the signal-generating element is a magnet whose poles are arranged next to each other as seen from the signal-generating element in the direction of the sensor element.

According to another embodiment of the invention, it is provided that, between the signal-generating element and the sensor element, there are counter-locking means that interact with the locking means. As a result, the sensor element is accommodated in such a way that it is protected against external mechanical effects. Moreover, this ensures that the gearshift lever and/or selector lever are properly secured or locked in the appropriate shifting position, without the position detection being detrimentally affected by the interaction between the signal-generating element and the sensor element.

The counter-locking means preferably is arranged so as to be permanently affixed to the housing.

The sensor element can be in the form of a printed circuit board or film. This means that it is easy to realize a pre-assembled unit that can be installed in the device in its pre-assembled form with very little effort. This also makes it very easy to replace the unit.

If the sensor element is arranged on a film, a particularly compact design can be achieved since the film does not take up much space. The arrangement of the sensor element on a printed circuit board allows a precise positioning of the sensor element by aligning the printed circuit board, so that, the sensor element is, in fact, placed exactly in the prescribed position when the printed circuit board is installed.

It can also be provided that the sensor element is firmly connected to the counter-locking means. As a result, it is possible to dispense with an additional component such as, for instance, a printed circuit board. Also, it becomes easy to install the sensor element since the sensor element and the counter-locking means have already been firmly connected to each other in a pre-assembly step, thus forming a pre-assembled unit.

A very firm and sturdy connection of the sensor element and the counter-locking means is achieved when the sensor element is molded into the counter-locking means. For instance, the sensor element can be sheathed by the material of the counter-locking means, e.g. plastic, so that the sensor element is protected against external mechanical stress. In this context, this measure also aims to ensure that the device according to the invention is highly fail-safe.

According to a preferred embodiment of the invention, it is provided that the sensor element delivers an analog signal as the measured value. As a result, positions of the gearshift lever and/or selector lever can also be detected that are outside of the sensor range that is of relevance for shifting the transmission. The information that can be acquired in this manner allows software to check whether the gearshift lever and/or selector lever is actually in a pre-selected shifting position. By using a sensor element with an analog signal as the measured value, it is very easy to obtain shifting information about the actual position of the gearshift lever and/or selector lever, so that a very high level of reliability against malfunction and failure can be achieved.

This is also the aim of the measure to the effect that the sensor element delivers, as the measured value, an analog signal that is dependent on the plus-minus sign. This means that the sensor element provides two separate pieces of information about the position or movement of the gearshift lever and/or selector lever, thereby further reducing the risk of an erroneous determination of the selected position of the gearshift lever and/or selector lever.

In an advantageous embodiment of the device according to the invention, it is provided that, as the measured value, the sensor element delivers a signal whose plus-minus sign changes when there is a change from a selectable position of the gearshift lever and/or selector lever into another selectable position of the gearshift lever and/or selector lever. Such an embodiment can be realized in that—for example, adjacent—partial elements of the sensor are oriented in opposite directions and/or are connected oppositely. In particular, the adjacent partial elements of the sensor can be, for instance, coils that are connected in series and that have opposite polarity.

Of course, according to another embodiment of the invention, it can also be provided that the sensor element delivers a digital signal as the measured value. The digital signal here can be dependent on the plus-minus sign.

It lends itself for at least one sensor element to be a Hall sensor. This allows for an inexpensive sensor element.

It also lends itself for the sensor element for detecting the positions of the gearshift lever and/or selector lever to be configured in a shift gate. For purposes of detecting the positions of the gearshift lever and/or selector lever, the sensor element can be configured in a shift gate with manually selectable gears.

As an alternative or in addition thereto, it can naturally also be provided that the sensor element for detecting positions of the gearshift lever and/or selector lever is configured in a shift gate with automatically selectable modes.

According to an independent idea of the invention—which can also be disassociated from the consideration as to whether, as the measured value, the sensor element delivers a signal, especially an analog signal, that is dependent on the plus-minus signal, or whether, as the measured value, the sensor element delivers a signal, especially an analog signal, whose plus-minus sign changes when there is a change from a selectable position of the gearshift lever and/or selector lever into another selectable position of the gearshift lever and/or selector lever—the sensor element can advantageously be arranged at least partially between two selectable positions of the gearshift lever and/or selector lever. This ensures that, when the gearshift lever and/or selector lever is swiveled into the one selectable shifting position as well as into the other selectable shifting position, the sensor element delivers a signal that is sufficiently strong and can be evaluated, without two sensor elements having to be used for this purpose. Consequently, this translates into a simplification especially of the device according to the invention, since only one sensor element is needed for two selectable shifting positions. This also accounts for lower costs.

According to an embodiment of the invention, at least two sensor elements are provided which, in order to detect the positions of the gearshift lever and/or selector lever in a shift gate or in order to detect a position in a shift gate, are configured in a position in another shift gate. This takes into consideration the possibility of a failure of one of the two sensor elements, so that the device according to the invention can then still ensure the detection of the position of the gearshift lever and/or selector lever.

According to another independent idea of the invention—which can also be disassociated from the consideration as to whether, as the measured value, the sensor element delivers a signal, especially an analog signal, that is dependent on the plus-minus signal, or whether, as the measured value, the sensor element delivers a signal, especially an analog signal, whose plus-minus sign changes when there is a change from a selectable position of the gearshift lever and/or selector lever into another selectable position of the gearshift lever and/or selector lever—at least two sensor elements can be provided, of which at least one sensor element is located at least partially between adjacent selectable positions of the gearshift lever and/or selector lever. This not only makes the device highly fail-safe but it also means that the device according to the invention for detecting several positions of the gearshift lever and/or selector lever is realized easily and cost-effectively. For instance, only two sensor elements are needed to detect three shifting positions of the gearshift lever and/or selector lever.

Preferably, the sensor elements should be distributed essentially along a shift gate. In this manner, the sensor elements are spatially associated directly with the signal-generating element when the locking means with the associated signal-generating element has been moved into the corresponding selectable position of the gearshift lever and/or selector lever. Consequently, the sensor element delivers a signal that is relatively strong and that can thus be evaluated very well.

According to another idea of the invention, it is provided that the device according to the invention for detecting the position of a gearshift lever and/or selector lever is part of a shifting device for a transmission that is particularly well-suited for use in a motor vehicle.

### DESCRIPTION OF THE DRAWINGS

Additional objectives, advantages, features and application possibilities of the present invention ensue from the description below of several embodiments on the basis of the drawings. In this context, all of the described and/or depicted features, either on their own or in any meaningful combination, constitute the subject matter of the present invention, also irrespective of their compilation in the claims to which they refer back.

The following is shown:

FIG. 1 a sectional view of a shifting device for a transmission, comprising a gearshift lever and/or selector lever, and a possible embodiment of the device according to the invention, for detecting the position of a gearshift lever and/or selector lever;

FIG. 2 a section of the shifting device from FIG. 1, showing the device according to the invention for detecting the position of a gearshift lever and/or selector lever;

FIG. 3 a section of the shifting device from FIG. 1, showing the device according to the invention for detecting the position of a gearshift lever and/or selector lever according to another embodiment;

FIG. 4 a top view of the shifting device from FIG. 1; and

FIG. 5 a top view from FIG. 4, with depictions of the signal curve of the sensor elements of the device according to the invention for detecting the position of the gearshift lever and/or selector lever, shown for the embodiments from FIGS. 2 and 3.

### DETAILED DESCRIPTION OF EMBODIMENTS

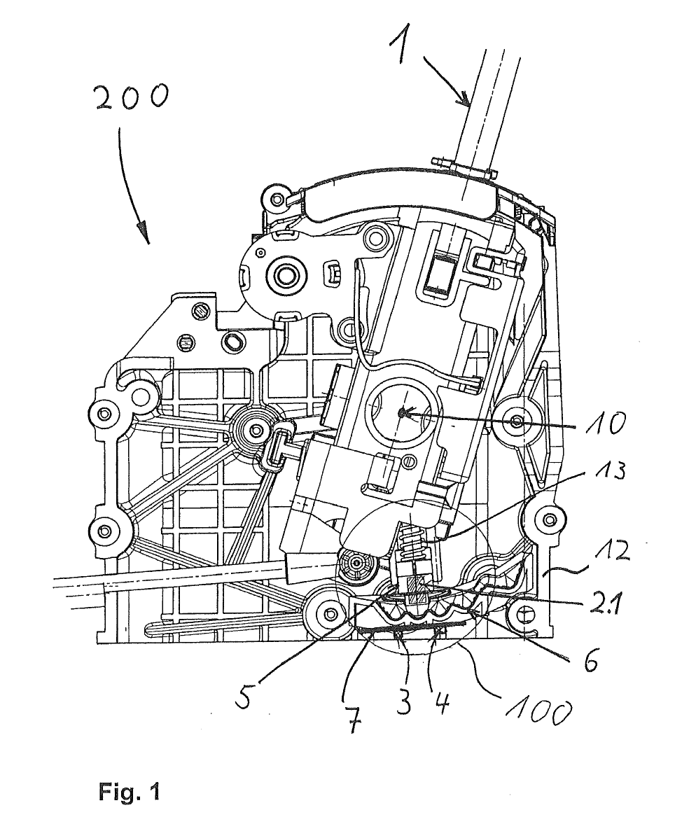

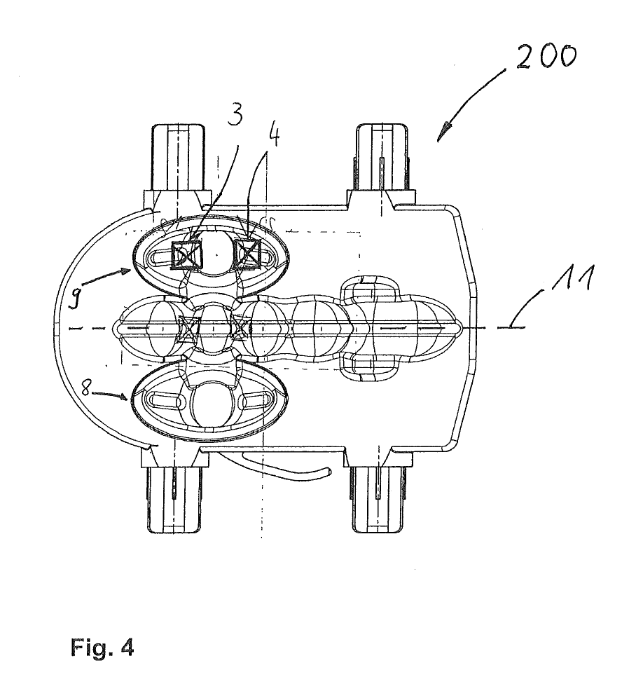

FIGS. 1, 2 and 4 schematically show a possible embodiment of a shifting device 200 for an automatic transmission with an additional manual shifting function. The shifting device 200 controls the transmission of a motor vehicle and/or its drive directly. The shifting device 200 has a gearshift lever and/or selector lever 1 that can be moved into various positions by an operator. Towards this end, the gearshift lever or selector lever 1 can be moved in such a way that various automatically selectable modes such as, for instance, “P”, “R”, “N”, “D”, “S” can be selected in a first shift gate, and individual manually shiftable gears can be selected in a second shift gate 9, making it possible to shift between a prescribed mode of the first shift gate 8 and a neutral position “M” of the second shift gate 9 via a cross-shift gate. In the second shift gate 9, starting from the neutral position “M”, swiveling the selector lever 1 into an “M+” position and an “M−” position effectuates an upshifting and downshifting of the manual gears, respectively. In order to select the modes in a shift gate 8 or 9, the gearshift lever and/or selector lever 1 is mounted so as to pivot around a first rotational axis 10. In order to shift the gearshift lever and/or selector lever 1 over from the first shift gate 8 into the second shift gate 9 and vice-versa, it is mounted so as to pivot around a second rotational axis 11, as can especially be seen in FIG. 4. The first rotational axis 10 and the second rotational axis 11 are preferably arranged at an angle of essentially 90° with respect to each other.

As can especially be seen in FIG. 1, the shifting device 200 has a locking means 5 that is associated with the gearshift lever and/or selector lever 1 and that interacts with the counter-locking means 6. The counter-locking means 6 is arranged so as to be affixed, preferably detachably, to the housing 12 of the shifting device 200 or else detachably joined to an intermediate part connected to the housing 12. The locking means 5 and the counter-locking means 6 that interact with it serve to lock the gearshift lever and/or selector lever 1 in selectable shifting positions at least to the extent that the operator of the gearshift lever and/or selector lever 1 notices some resistance when she/he has moved the gearshift lever and/or selector lever 1 into the appropriate shifting position.

Preferably, the locking means 5 is configured as a latching element that is preferably arranged on the gearshift lever and/or selector lever 1 in such a way that it can be moved against the pressure of a spring element 13. The locking means 5 is also preferably arranged at the free end of the gearshift lever and/or selector lever 1 that is located in the housing 12 of the shifting device 200 and that is preferably opposite—relative to the first rotational axis 10—to the knob (not shown here) of the gearshift lever and/or selector lever 1 so that the operator can grip it. The locking means 5 or the latching element is preferably configured so as to be round, preferably spherical, at its end facing the counter-locking means 6.

The counter-locking means 6, which is preferably configured as a counter-latching means, has a receptacle 14 into which the latching element 5 can engage. When the latching element 5 has been moved into the receptacle 14 of the counter-locking means 6, the gearshift lever and/or selector lever 1 is held in the shifting position. This shifting position is left again by pressing the gearshift lever and/or selector lever 1, as a result of which the latching element 5 is taken out of its latching position against the pressure of the spring element 13.

The counter-locking means 6 or the counter-latching means are preferably shaped so as to be flat, particularly due to a shared surface or the pre-tensioning, and they have several receptacles 14 for the locking means 5 or for the latching element. As a result, the latching element 5 can latch against the counter-latching means 6 in several shifting positions of the gearshift lever and/or selector lever 1. The latching element 5 can also latch against the counter-latching means 6 in the one shift gate 8 as well as in the other shift gate 9. By the same token, latched shifting positions of the gearshift lever and/or selector lever 1 in the one shift gate 8 can also be reached in the other shift gate 9.

Especially as shown in FIG. 1, a device for detecting the position of the gearshift lever and/or selector lever 1 is associated with the shifting device 200. By means of the device 100, the movement of the gearshift lever and/or selector lever 1, especially the position of the gearshift lever and/or selector lever 1, is detected by means of sensors and, following an evaluation by an evaluation unit (not shown here), the transmission or the drive of the motor vehicle is controlled by means of an actuator (not shown here). For this purpose, the device 100 has a signal-generating element 2.1 and at least one, preferably two, sensor elements 3, 4 that detect the signal of the signal-generating element 2.1. Preferably, the signal-generating element is configured as an element 2.1 that generates a magnetic field, for example, it is in the form of a permanent magnet. Preferably, the sensor element 3 or 4 that detects the magnetic field of the signal-generating element 2.1 is configured as a Hall sensor.

The signal-generating element 2.1 is preferably associated with the locking means or latching element 5, and it especially arranged in the vicinity of the end of the latching element 5 that can be made to engage with the counter-latching means 6. In this context, the signal-generating element 2.1 is preferably surrounded, especially sheathed, by the latching element 5, which is preferably made of plastic.

The sensor elements 3, 4 are preferably firmly arranged on a printed circuit board 7, whereby the printed circuit board 7 is arranged underneath the counter-latching means 6, so that the counter-latching means 6 is situated between the printed circuit board 7 and the latching element 5. The printed circuit board 7, along with the sensor elements 3, 4, is mounted, preferably detachably, on the counter-latching means 6 and/or on the housing 12 of the shifting device 200.

The sensor elements 3, 4 are preferably arranged at a distance from each other on the printed circuit board 7. The sensor elements 3, 4 are preferably positioned essentially in the direction of the shift gate 9 whose shifting positions are to be detected.

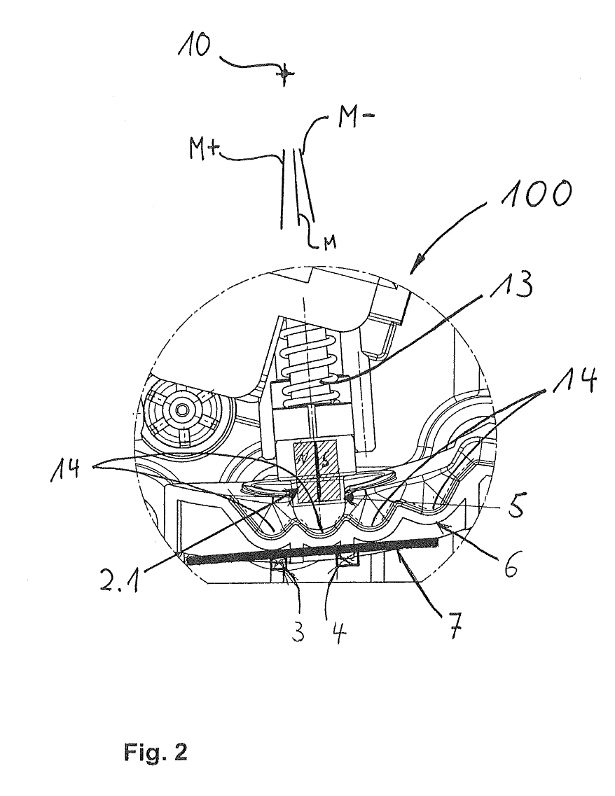

Especially as can be seen in FIG. 2, the embodiment of the device 200 according to the invention shown there pertains to the arrangement of the sensor elements 3, 4 in such a manner that the shifting positions “M+” and “M−” as well as the neutral position “M” of a so-called Tiptronic transmission are detected. For this purpose, the gearshift lever and/or selector lever 1 is situated in the shift gate 9. The sensor elements 3, 4 are arranged at least partially between adjacent selectable positions M+, M or M, M− of the gearshift lever and/or selector lever 1.

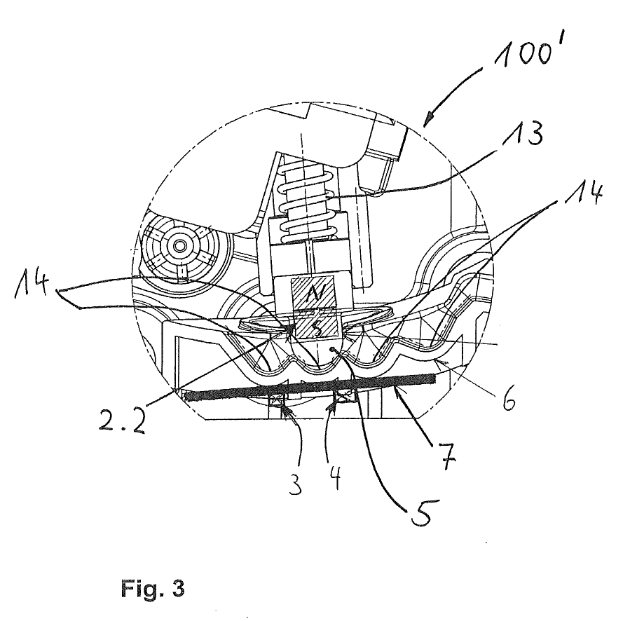

FIG. 2 also shows a detailed view of the embodiment of the device 100 according to the invention for detecting the position of the gearshift lever and/or selector lever 1 in accordance with FIG. 1. The signal-generating element 2 is formed by a magnet. The N, S poles of the magnet are arranged so as to be next to each other, as seen from the signal-generating element 2 and in the direction of the sensor elements 3, 4. FIG. 3 shows the arrangement of the N, S poles of a signal-generating element 2.2 of a device 100′ for detecting the position of a gearshift lever and/or selector lever 1 in an alternative embodiment. The signal-generating element 2.2 is arranged to the rear, as seen in the direction of the sensor elements 3, 4.

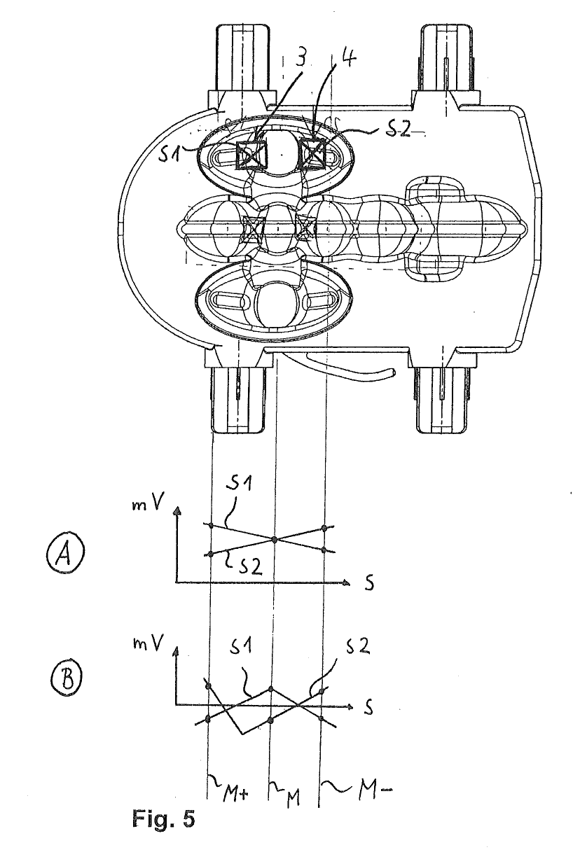

The signals of the sensor elements 3, 4 resulting from the different arrangements of the N, S poles of the signal-generating element 2.1 or 2.2 are depicted in FIG. 5. The sensor elements 3, 4 are arranged here in such a manner that they deliver an analog signal as the measured value. Diagram A in FIG. 5 shows the curve of the analog signal as a function of the appertaining position S of the gearshift lever and/or selector lever 1 for the embodiment of the signal-generating element 2.1 according to FIG. 2. The sensor element 3 here delivers the signal S1 while the sensor element 4 delivers the signal S2, whereby both signals S1 and S2 are preferably voltage signals.

When the selector lever 1 is moved from a shifting position into another shifting position, for instance, from the shifting position “M+” into the shifting position “M−”, the analog signal S1 as well as the analog signal S2 change essentially linearly.

Preferably, the signals that are present in the shifting positions “M+”, “M” or “M”, “M−” of the gearshift lever and/or selector lever 1 serve as calibration values for the evaluation unit (not shown here). In this context, the position “M”, which constitutes the neutral position for the gearshift lever and/or selector lever 1 of a so-called Tiptronic transmission, is preferably a latching position in which the latching element 5 is latched in one of the receptacles 14 of the counter-latching means 6. The shifting positions “M+” and “M−” are the shifting positions that can be tipped, and preferably the latching means 5 in these shifting positions does not engage with one of the receptacles 14 of the counter-latching means 6.

Diagram B of FIG. 5 shows the signal curve of the sensor elements 3, 4 in the embodiment of the signal-generating element 2.2 according to FIG. 3. The diametric permanent magnet provided there causes a reversal of the plus-minus sign of the measured value provided by the sensor elements 3, 4, as can be seen on the basis of the curve of the sensor signals S1 and S2 in diagram B of FIG. 5. Therefore, not only the analog signal value as such, but also the plus-minus sign provide additional information that can be evaluated, thus rendering the device highly fail-safe and accounting for an optimal error recognition capability if malfunctions should occur in the shifting device 200.

While preferred embodiments of the invention have been described and illustrated here, various changes, substitutions and modifications to the described embodiments will become apparent to those of ordinary skill in the art without thereby departing from the scope and spirit of the invention.

### LIST OF REFERENCE NUMERALS

1 gearshift lever and/or selector lever

2.1 signal-generating element

2.2 signal-generating element

3 sensor element

4 sensor element

5 locking means, latching element

6 counter-locking means, counter-latching means

7 printed circuit board

8 first shift gate

9 second shift gate

10 first rotational axis

11 second rotational axis

12 housing

13 spring element

14 receptacle

100 detection device

100′ detection device

200 shifting device

M+ shifting position of the shift gate 9 for manually shiftable gears

M− shifting position of the shift gate 9 for manually shiftable gears

M neutral position of the shift gate 9 for manually shiftable gears

S1 analog signal

S2 analog signal

N pole of the signal-generating element

S pole of the signal-generating element

1. A device (100, 100′) for detecting the position of a gearshift lever and/or selector lever (1) for a transmission, comprising:
a signal-generating element (2.1; 2.2) that can be moved together with the gearshift lever and/or selector lever (1);
at least one sensor element (3, 4) that detects the signal from the signal-generating element (2.1; 2.2), wherein the sensor element (3, 4) delivers, as a measured value, an analog signal (S1, S2) that is dependent on a plus-minus sign, and/or the sensor element (3, 4) delivers, as an alternative measured value, a signal that may be an analog signal, that is whole plus-minus signal sign changes when there is a change from a selectable position (M+, M; M, M−) of the gearshift lever and/or selector lever (1) into another selectable position (M+, M; M, M−) of the gearshift lever and/or selector lever (1); and
a locking means (5) for the gearshift lever and/or selector lever (1) associated with the signal-generating element (2.1; 2.2).

2. The device according to claim 1, wherein the signal-generating element (2.1; 2.2) is firmly connected to the locking means (5).

3. The device according to claim 1, wherein the signal-generating element (2.1; 2.2) is arranged inside the locking means (5).

4. The device according to claim 1, wherein the locking means (5) is a plastic part and the signal-generating element (2.1; 2.2) is at least partially surrounded by the material of the locking means (5).

5. The device according to claim 1, wherein the signal-generating element (2.1; 2.2) is a magnet.

6. The device according to claim 1, wherein the signal-generating element (2.1; 2.2) is a magnet whose poles (N, S) are arranged one behind the other as seen in the direction of the sensor element (3, 4).

7. The device according to claim 1, wherein the signal-generating element (2.1; 2.2) is a magnet whose poles (N, S) are arranged next to each other as seen in the direction of the sensor element (3, 4).

8. The device according to claim 1, wherein between the signal-generating element (2.1; 2.2) and the sensor element (3, 4), there are counter-locking means (6) that interact with the locking means (5).

9. The device according to claim 1, wherein the sensor element (3, 4) is arranged on a printed circuit board (7) or film.

10. The device according to claim 8, wherein the sensor element is firmly connected to the counter-locking means.

11. The device according to claim 1, wherein the sensor element (3, 4) is arranged at least partially between two selectable positions (M+, M; M, M−) of the gearshift lever and/or selector lever (1).

12. The device according to claim 1, wherein the at least one sensor element (3, 4) is a Hall sensor or a linear sensor.

13. The device according to claim 1, wherein for purposes of detecting the position of the gearshift lever and/or selector lever (1), the sensor element (3, 4) is configured in a shift gate (9).

14. The device according to claim 1, wherein at least two sensor elements (3, 4) are provided, of which at least one sensor element (3, 4) is located at least partially between adjacent selectable positions (M+, M; M, M−) of the gearshift lever and/or selector lever (1).

15. The device according to claim 14, wherein the sensor elements (3, 4) are distributed essentially along a shift gate (9).

16. A shifting device (200) for a transmission, especially for use in a motor vehicle, having a device (100, 110′) for detecting the position of a gearshift lever and/or selector lever (1), according to claim 1.

17. The device (100) according to claim 8 wherein the sensor element (3, 4) is molded into the counter-locking means (6).

18. A shifting device for a vehicle transmission, comprising:
a detection device having (a) a signal-generating element that can be moved together with the gearshift lever and/or selector lever, (b) at least one sensor element that detects the signal from the signal-generating element, wherein the sensor element delivers, as a measured value, an analog signal that is dependent on a plus-minus sign, and/or the sensor element delivers, as an alternative measured value, a signal that may be an analog signal, that is whole plus-minus signal sign changes when there is a change from a selectable position of the gearshift lever and/or selector lever into another selectable position of the gearshift lever and/or selector lever, and (c) a locking means for the gearshift lever and/or selector lever associated with the signal-generating element.
